(19) United States
(12) Patent Application Publication
(10) Pub. No.: US 2012/0262914 A1
(43) Pub. Date: Oct. 18, 2012

(54) Lighting Device and Method for Upgrading a Lighting Device

(76) Inventors: Steffen Block, Lauterach (AT); Ales Markytan, Regensburg (DE); Christoph Neureuther, Regensburg (DE)

(21) Appl. No.: 13/502,326

(22) PCT Filed: Oct. 8, 2010
(86) PCT No.: PCT/EP2010/065068

§ 371 Date: Jul. 2, 2012

(30) Foreign Application Priority Data
Oct. 14, 2009 (DE) 10 2009 049 392.1

(51) Int. Cl. F21V 9/08; H05K 13/00

(52) U.S. Cl. 362/231; 29/592.1

(57) ABSTRACT

A lighting device comprising a first light source for emitting electromagnetic radiation having a first electromagnetic spectrum and a second light source for emitting electromagnetic radiation having a second electromagnetic spectrum, wherein the first and the second electromagnetic spectrum are different from each other, wherein an intensity maximum of the first electromagnetic spectrum lie within the range of the spectral sensitivity of the human eye, and wherein an intensity maximum of the second electromagnetic spectrum lies within the range of the spectral sensitivity of the visual organs of nocturnal insects.

The invention relates to a lighting device. Also disclosed is a method for upgrading an existing lighting device. The lighting device comprises two light sources which emit electromagnetic radiation having spectra which are different from each other.

Lighting devices can be used for lighting outdoor areas, in particular roads and squares.

Known from DE 296 16 286 U1 are street lights having optimized light distribution and optimized luminous efficiency.

One problem with lighting devices is that the light emitted can attract nocturnal insects.

This results in the contamination of the lighting device, since the insects leave secretions on the light.

Moreover, in the case of lighting devices based on mercury-vapor lamps, fluorescent lamps, metal-vapor lamps, incandescent lamps or sodium-vapor lamps, the insects may burn on the surface of the light, in particular on the hot light-exit surface of the light. This results in additional contamination of the light.

These two types of contamination result in degradation of the total luminous flux of the light and hence to impaired efficiency. To counteract this, frequent cleaning of the lights is essential. This amount of maintenance is time-consuming and expensive.

The present invention is based on the object of providing a lighting device which, in operation, is contaminated as little as possible by nocturnal insects.

The aforementioned object is achieved according to the invention by a lighting device with the features of the claim 1 or by a method with the features of the claim 12.

Further developments and refinements of the lighting device or of the method are disclosed in the dependent claims.

Embodiments of the lighting device have a first light source for emitting electromagnetic radiation having a first electromagnetic spectrum. They also have a second light source for emitting electromagnetic radiation having a second electromagnetic spectrum. The first and the second electromagnetic spectrum are different from each other. At least one intensity maximum of the first electromagnetic spectrum lies within the range of the spectral sensitivity of the human eye. At least one intensity maximum of the second electromagnetic spectrum lies within the range of the spectral sensitivity of the visual organs of nocturnal insects.

The maximum relative spectral emission of the light source occurs at the wavelength at which the intensity maximum lies.

Nocturnal insects are for example:
mayflies (Ephemeroptera)
stoneflies (Plecoptera)
beetles (Coleoptera)
thrips (Thysanoptera)
Heteroptera (bugs)
Homoptera (cicadas, hoppers, etc.)
lacewings (Neuroptera)
caddis-flies (Trichoptera)
butterflies (Lepidoptera)
flies and mosquitoes (Diptera, Nematocera)
ants, bees, wasps, etc. (Hymenoptera).

The first light source can be provided for lighting outdoor areas such as roads or squares. The light emitted should be of a color which is as pleasant as possible to the human eye, that is a light spectrum which at least partially resembles sunlight, and should be sufficiently bright.

In the present invention, the first light source is combined with a second light source. The second light source can emit ultraviolet, violet, blue or green light.

This can have the effect that when insects attracted by the first light source approach the first light source they are attracted much more strongly by the second light source. In the context of the present invention, the second light source can also be designated a light trap or insect trap.

The use of a light trap has the advantage that, before the insects come into contact with the first light source and hence could contaminate it, the insects fly in the direction of the light trap. This has the effect that the first light source or, more specifically, the light-exit surface or the translucent cover of the first light source is subject to much less contamination.

Advantageously, this slows down the deterioration of the efficiency the lighting device due to contamination by nocturnal insects. The cleaning and maintenance costs are reduced, in particular the maintenance intervals are extended. This reduces the costs of the upkeep of lighting devices, in particular outside lighting.

Exemplary embodiments describe a method for upgrading a lighting device by arranging a second light source on the lighting device comprising a first light source. The first light source emits electromagnetic radiation having a first electromagnetic spectrum. The second light source emits electromagnetic radiation having a second electromagnetic spectrum. The first and the second spectrum are different from each other. At least one intensity maximum of the first electromagnetic spectrum lies within the range of the spectral sensitivity of the human eye. At least one intensity maximum of the second electromagnetic spectrum lies within the range of the spectral sensitivity of the visual organs of nocturnal insects.

This method is particularly advantageous since it enables lighting devices which are already installed to be upgraded easily and inexpensively. In particular, it is not necessary to modify or dismantle the lighting device. It is possible to attach the light trap to the lighting device during operation.

In a particularly advantageous manner, the lighting device comprises a mast. The second light source can be installed on the mast in a particularly simple manner and variably with respect to its geometric arrangement.

In a further development of the method according to the invention, the lighting device is provided with a light comprising the first light source. The light trap can be attached directly to the light.

This further development has the advantage that lighting devices without a mast, for example with lights that are only connected to wires, can be upgraded with a light trap without any problems.

Preferably, the light trap emits electromagnetic radiation at least partially from the UV range to the green spectral range.

In a preferred manner, the intensity maxima of the radiation emitted by the light trap emitted lie within the ranges of the maximum spectral sensitivity of nocturnal insects.

This includes the ultraviolet spectral range with a wavelength of approximately 340 nm, which is not perceptible to the human eye.

The light trap can also emit in the blue-violet spectral range at a wavelength of approximately 450 nm.

The light trap can also emit in the blue-green spectral range at a wavelength of approximately 500 nm.

The light trap can emit electromagnetic radiation from a single spectral range or from a combination of the aforementioned spectral ranges.

Particularly advantageous is a light trap with an electromagnetic spectrum that is at least predominantly in the ultraviolet spectral range. The maximum spectral sensitivity of nocturnal insects lies within this spectral range.

This causes insects to be enticed away from the first light source to the maximum degree while there is no change in the human perception of light.

Light traps that emit violet or blue light are particularly advantageous, since here, once again, on average, nocturnal insects have very high spectral sensitivity. Although humans perceive light in these spectral ranges, they do not find it uncomfortable.

However, however to ensure the function of a light trap that emits exclusively or predominantly visible light, in the present case therefore violet or blue light, it is mandatory, in the immediate vicinity of first light source, for the radiation intensity of the light trap in these spectral ranges to be greater than that of the first light source. Only then do the nocturnal insects prefer the light trap to the first light source.

The effect described here can be intensified in that the lighting means used for the first light source emit as weakly as possible in the ranges of high spectral sensitivity of insects, in the present case, therefore, in the violet or blue spectral range.

In a further embodiment, light traps are provided that emit electromagnetic radiation with at least one intensity maximum in the green spectral range. Although, the spectral sensitivity of nocturnal insects is generally weaker in the green spectral range than in the ultraviolet, violet or blue spectral ranges, even this embodiment can be advantageous if the first light source emits electromagnetic radiation with the lowest possible intensity in the ultraviolet, violet, blue and green spectral ranges.

The lighting device can be designed such that the second light source is weakly radiating compared to the first light source.

This is particularly advantageous since this ensures that the light trap does not attract even more nocturnal insects. In other words, the effect of the lowest possible radiation intensity of the light trap is that only insects that were attracted by the first light source enter the light trap.

In addition, the amount of energy required to operate the light trap is kept low.

The first and the second light source can, independently of each other, be based on so-called conventional lighting means, such as incandescent lamps, mercury-vapor lamps, metal-vapor lamps, fluorescent lamps or sodium-vapor lamps.

However, preferably only the first light source is equipped with so-called conventional lighting means.

Sodium-vapor lamps are particularly suitable for outdoor lighting. They emit light directly in the spectral range visible to humans and do not emit at all in the UV range.

Mercury-vapor lamps, in which the mercury discharge takes place at high pressures and fluorescent lamps, in which the mercury discharge takes place at low pressure, are suitable for lighting outdoor areas, since the primarily emitted line in the UV range is, to a large extent, converted by means of a fluorescent material into light visible to humans. The remaining UV component is to a large extent absorbed by the glass surrounding the discharge arrangement.

Incandescent lamps are also widely used for outdoor lighting, but have poor energy efficiency.

Preferably, fluorescent lamps are used for the first light source since, during operation, their outer casing only heats up to a temperature in the range of around 40° at which insects coming into contact with the outer casing do not burn.

Even more advantageous with respect to the minimization of heat development in the first light source is the use of light emitting diodes (LEDs) or organic light emitting diodes (OLEDs). Although insects are still attracted by light similarly to the case with so-called conventional lighting means, they are no longer burnt on the light-exit surface.

However, nocturnal insects still result in the contamination of the light-exit surface due to their secretions.

The first light source, the so-called conventional lighting means, can be upgraded by the implementation of the so-called “retrofit approach” with a LED or OLED unit or in other words replaced by a LED or OLED unit.

Although the light trap can be implemented with so-called conventional lighting means, preference should be given to LEDs or OLEDs.

A suitable choice of the type and/or the doping of the light-emitting diode or the type of organic light-emitting diode enables the intensity maxima of the emitted electromagnetic radiation from the light trap to be selected such that they lie within the ranges of the maximum spectral sensitivity of nocturnal insects.

Preferably light-emitting diodes with narrow-band emission curves are used that emit electromagnetic radiation in the ultraviolet, violet, blue or green spectral ranges.

In the case of the use of a light trap based on LEDs or OLEDs, the light trap does not have to be cleaned as intensively as the first light source. The insects do not burn on contact with the light-exit surface. The contamination of the light trap is then exclusively caused by the insects' secretions.

The second light source can comprise a shading means.

This shading means is preferably arranged about the second light source such that its electromagnetic radiation is to a large extent concealed from the environment.

This is advantageous for several reasons. On the one hand, this ensures that the nocturnal insects attracted by the first light source only perceive the light trap when they are already very close to the first light source. Therefore, the light trap only attracts insects that were originally attracted by the first light source. This means that the use of a light trap does not attract any additional insects.

On the other hand, when using light traps that exclusively or partially emit ultraviolet light, the use of shading prevents any damage to the human eye.

The shading means have different shapes.

In one embodiment, the shading means is implemented in the shape of a hemisphere.

A shading means in a bent shape can also be advantageous. A shading means in a bent shape is more favorable from the point of view of production technology since it is easier and hence less expensive to produce than a shading means in shape of a hemisphere.

A combination of a hemisphere and a bent shape can advantageous.

It is particularly advantageous for the shading means to be made of opaque material. Depending upon the spectrum of the light trap used, the material must be opaque to electromagnetic radiation in the ultraviolet and/or in the blue and/or in the green spectral ranges.

In a particularly simple embodiment, the material is an opaque metal.

The first light source and the second light source are arranged on the lighting device such that nocturnal insects only perceive the first light source and the second light source simultaneously in the immediate vicinity of the first light source, that is the first and the second light source are in competition from the viewpoint of the insects. In this way, it can be ensured that the use of a light trap does not attract any additional nocturnal insects. This condition is fulfilled in the connection with the intensity of the radiation from the light trap and with the use of a shading means.

According to a further embodiment of the invention, the lighting device has a control device. This is set up to control the electromagnetic spectra and/or the intensities of the emitted electromagnetic radiation from the first light source and/or the second light source individually or jointly.

This can have the effect that depending upon the local conditions at the location of the lighting device, such as, for example temperature, light conditions or time of day, the two light sources are controlled such that the arrangement of first light source and light trap functions as energy-efficiently as possible and the fewest possible insects contaminate the light-exit surface of the first light source.

The control device is an analog or digital circuit with which the light sources, preferably the light-emitting diode(s) are controlled. It can be used to switch the light sources on or off or to dim them.

It is also possible to change the emission spectrum. This can take place by changing the current intensity and/or by pulse width modulation.

The digital circuit can have an internal calendar function. Calendar data are stored in an associated memory. These data can be read out and forwarded to a control device. Different control programs can be executed in a processor. It is possible to make the daily lighting time of the light sources dependent upon the date. This reduces the energy consumption of the lighting device.

The control is also able to provide adaptation to different times of the year. For example, during the operation of the first light source, the light trap can remained switched off at times at which there are hardly any flying insects. This is the case in winter, for example. This leads to further energy savings.

Preferably, the lighting device comprises a sensor, which determines the measured variables necessary for the control of the lighting device, such as temperature, atmospheric humidity, ambient luminosity or visibility conditions in real time and forwards them to the control device for processing.

The attractiveness of artificial light sources to nocturnal insects is dependent upon numerous factors, such as, for example:
the intensity of the light source, i.e. the brightness
the light spectrum, i.e. the light color
the height above ground which in which the light source is attached—the presence of competing light sources
the different spectral sensitivities of different types of nocturnal insects

The attraction to nocturnal insects increases with increasing brightness and an increasing height of the light source. Another very decisive factor is the fact that, in the case of competing light sources, many more insects fly toward the light source with the more attractive spectrum, which therefore primarily emits in the ranges of electromagnetic radiation in which nocturnal insects have the maxima of their spectral sensitivity.

The invention is independent of the detailed design of the lighting device and, at the same time, any dimensions and geometric arrangements of the two light sources are possible.

### BRIEF DESCRIPTION OF THE DRAWINGS

The following explains the invention in more detail with reference to several exemplary embodiments:

FIG. 1a to 1c show exemplary embodiments of a lighting device in a schematic view;

FIGS. 2a to 2c show exemplary embodiments of lighting device with a shading means in a schematic view;

FIGS. 3a and 3b show exemplary embodiments of a further lighting device in a schematic view;

FIG. 4 is a schematic graph plotting the spectral sensitivities of visual organs of humans and nocturnal insects; and

FIG. 5 shows the electromagnetic spectra of light-emitting diodes, which can be used for the light trap according to the invention compared to the spectral sensitivity of the human eye.

The same, similar or equivalent elements are given the same reference characters in the in the figures. The figures and relative proportions in size of the elements shown in the figures are not drawn to scale, instead some elements are shown exaggeratedly large for better clarity and better intelligibility.

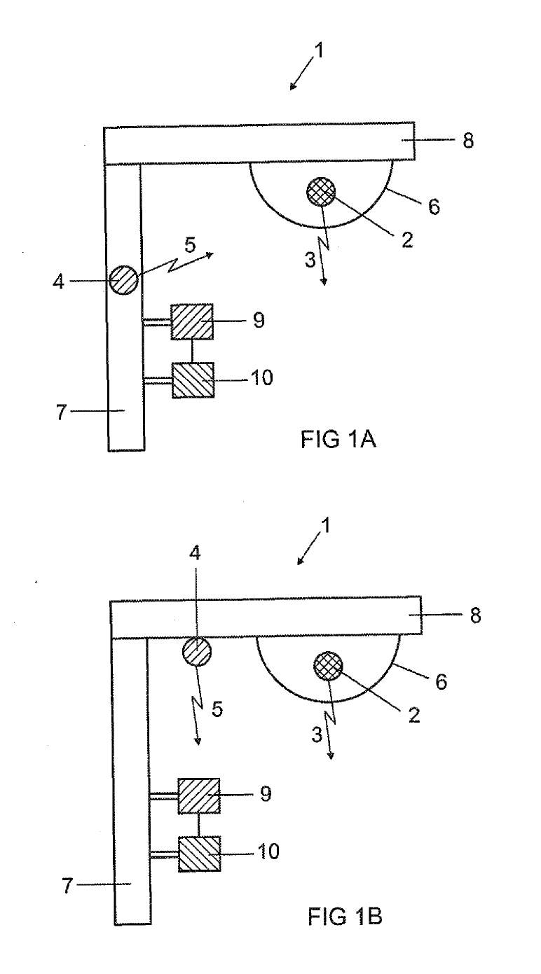

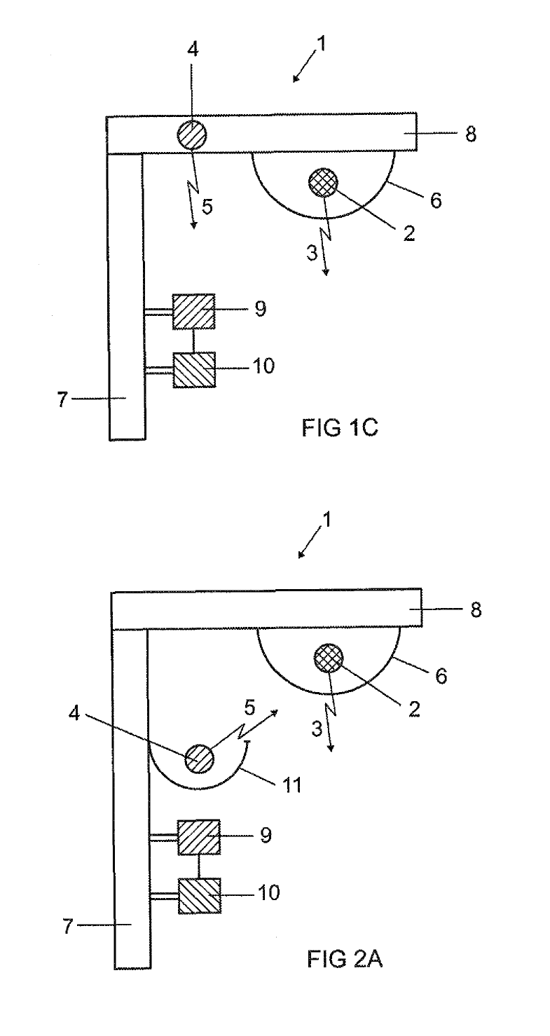

FIG. 1a shows a first exemplary embodiment of a lighting device 1. A first light source 2 is component of a light 8. The light 8 comprises a light-exit surface 6 enclosing the first light source 2. The light 8 is attached to a mast 7. A second light source 4 attached directly to the mast 7. The first light source 2 emits electromagnetic radiation 3 with a first electromagnetic spectrum. The second light source 4 emits electromagnetic radiation 5 with a second electromagnetic spectrum. A control device 9 and a sensor 10 are also attached to the mast 7. The control device 9 and the sensor 10 are connected to each other.

The light-exit surface 6 protects the first light source from exposure to the weather.

The first electromagnetic spectrum 3 and the second electromagnetic spectrum 5 are at least partially different from each other.

Here, the first light source 2 is selected such that an intensity maximum of the first electromagnetic spectrum lies within the range of the spectral sensitivity 21 of the human eye. On the other hand, the second light source 4 is selected such that an intensity maximum of the second electromagnetic spectrum lies within the range of the spectral sensitivity 22 of the visual organs of nocturnal insects.

The electromagnetic radiation 5 emitted by the second light source 4, is intended to entice nocturnal insects away from the first light source 2 integrated in the light 8. Therefore, the second light source 4 is designed such that it shows narrow-band emission lines in the UV range at approximately 340 nm and/or in the blue-violet spectral range at approximately 450 nm and/or in the blue-green spectral range at approximately 500 nm.

Compared to the first light source 2, the second light source 4 is weakly radiating in order not to attract any additional nocturnal insects.

The light 8 can provide as the light source incandescent lamps, mercury-vapor lamps, metal-vapor lamp, fluorescent lamps or sodium-vapor lamps. Lights 8 based on LEDs or OLEDs are also used. The light 8 can also be upgraded with LEDs or OLEDs.

The fact that the light trap 4 is fastened directly to the mast 7 facilitates the subsequent upgrading of the lighting device 1 with the light trap 4.

The control device 9 can also be attached to a location other than the mast 7. For example, the control device 9 is also attached in the mast 7 or in the light 8 or on the exterior of the light 8.

The control device 9 controls the electromagnetic spectra and/or the intensities of the emitted electromagnetic radiation from the first light source 2 and/or the second light source 4. This can take place individually or jointly.

In order to enable the variation of the electromagnetic spectra 3, 5 and the intensities of the first light source 2 and the second light source 4 dynamically and without human intervention, a sensor 10 for detecting measured variables, such as temperature, atmospheric humidity, ambient luminosity and visibility conditions is provided in each case at the location of the lighting device 1.

The sensor 10 can also be attached at a place other than on the mast. For example, the sensor 10 can also be attached in the mast 7, directly on the light 8 or in the light 8.

In order to be able to detect ambient variables, such as brightness or temperature, here, the sensor has to be in optical and thermal contact with the environment. The optical contact can be established by a light window that transmits light. The thermal contact can be implemented by a temperature sensor.

The sensor 10 and the control device 9 are connected to each other for data transmission. In addition to the data supplied to the control device 9 from the sensor 10, it is also possible for parameters for controlling the lighting device 1 from outside to be entered in the control device 9.

Unlike the exemplary embodiment in FIG. 1a, in the exemplary embodiment in FIG. 1b, the light trap is fastened directly on the light 8 in the form of a second light source 4.

This arrangement is also suitable for the upgrading of the lighting device 1 with a light trap 4.

Here, the advantage over the exemplary embodiment in FIG. 1a is the fact that the first light source 2 and the second light source 4 can be attached at a smaller distance from each other. This means that a lower radiation intensity of the light trap is required to attract nocturnal insects, which were originally attracted by the first light source 2, to the light trap 4.

Unlike the exemplary embodiment in FIGS. 1a and 1b, in the exemplary embodiment in FIG. 1c, the second light source 4 is integrated in the light 8.

However, as before, the first light source 2 and the second light source 4 are spatially separate from each other. The first light source 2 has its own light-exit surface 6. The exemplary embodiment in FIG. 1c is less suitable for upgrading an already existing lighting device 1 with a light trap 4.

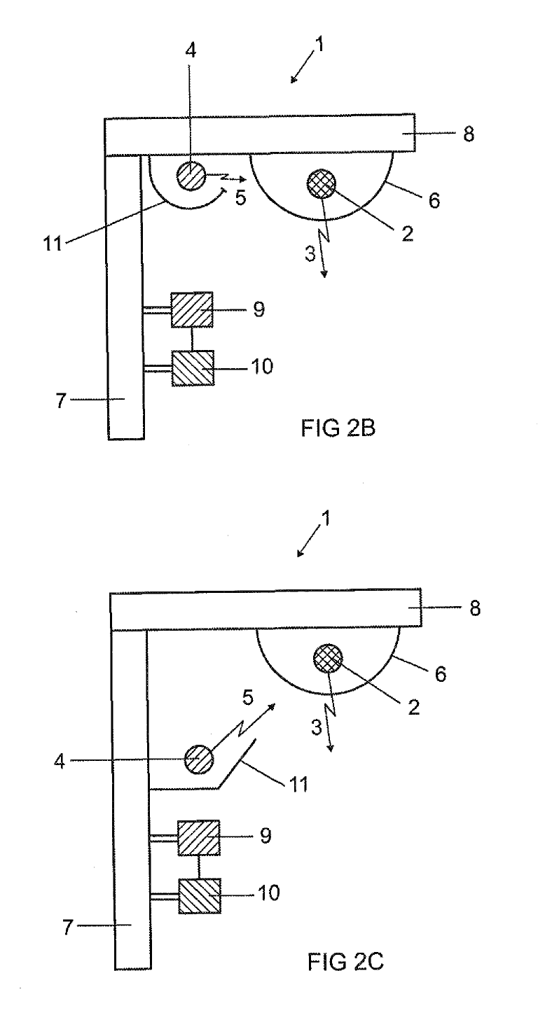

Unlike the exemplary embodiments in FIGS. 1a to 1c, FIG. 2a shows a lighting device 1 in which a shading means 11 is arranged around the second light source 4.

The shading means 11 can be embodied in the shape of a hemisphere.

The shading means 11 can be opaque to electromagnetic radiation from the ultraviolet to the green spectral range.

The material provided for the shading means 11 can be a metal.

The shading means 11 can be arranged together with the second light source 4 on the mast 7.

Here, the opening of the shading means 11 should be selected such that the nocturnal insects only perceive the light of the light trap 4 when they are located in the immediate vicinity of the first light source 2. In other words: the first light source 2 and the second light source 4 are arranged on the lighting device 1 such that nocturnal insects only perceive the first light source 2 and the second light source 4 simultaneously in the immediate vicinity of the first light source 2. Only then, are these competing light sources. This ensures the light trap 4 does not attract any additional insects.

Unlike the exemplary embodiment in FIG. 2a, FIG. 2b shows a lighting device 1 with a second light source 4 around which a shading means 11 is arranged in turn. However, here the unit comprising the second light source 4 and the shading means 11 is fastened directly on the light 8. This has the advantage that the opening of the shading means 11 toward the first light source 2 can be particularly small.

This further minimizes the probability of additional nocturnal insects being attracted by the light trap 4.

FIG. 2c shows an exemplary embodiment of a lighting device 1 in which the shading means 11 is embodied in a bent shape and is fastened to the mast 7 with the second light source 4.

The shading means 11 in bent shape with the second light source 4 can also be fastened directly to the light 8.

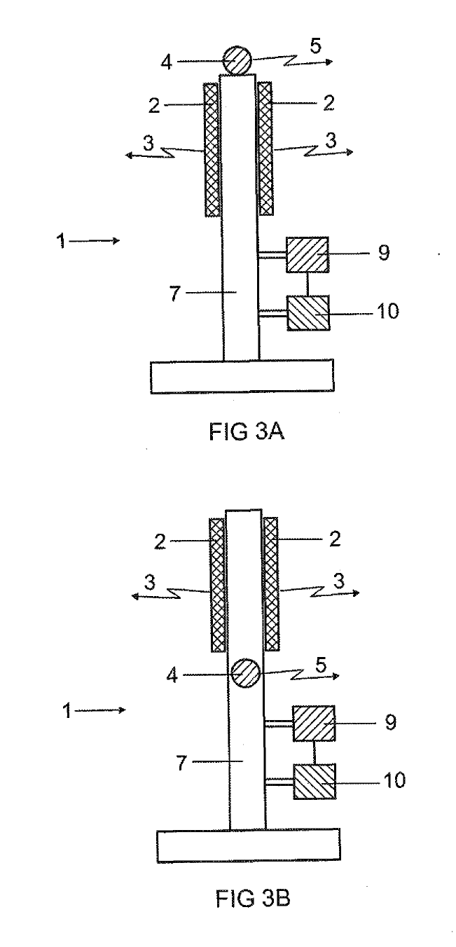

FIG. 3a shows a further exemplary embodiment of a lighting device 1. A plurality of light-emitting diodes is fastened along two rows on the mast 7 as the first light source 2. The light trap 4 can be arranged above the row of light-emitting diodes, preferably on the tip of the mast 7. This exemplary embodiment also has a control device 9 and sensor 10 which interact according to the invention and are fastened to the mast 7.

The individual light-emitting diodes can be arranged according to the desired direction of radiation. The direction of radiation can also be influenced by optical elements although this in not shown in this figure. It is also possible for more than two rows of light-emitting diodes to be provided in order to achieve more homogeneous lighting and the greatest possible distance of the lighting devices (1) from each other.

The direction of radiation of the first light source 2 can be set by the aforementioned optical elements such that the electromagnetic radiation 3 for lighting the road only is only emitted downward toward the road. The emission of the electromagnetic radiation 3 upward and in the horizontal direction can be reduced.

This measure causes fewer nocturnal insects to be attracted by the first light source 2.

Unlike the exemplary embodiment described in FIG. 3a, in the exemplary embodiment in FIG. 3b, the second light source 4 is arranged on the mast 7 below the first light source 2.

Compared to the exemplary embodiment in FIG. 3a, this can be advantageous since the fact that the light trap 4 is attached to the mast at a lower height means that fewer additional nocturnal insects are attracted.

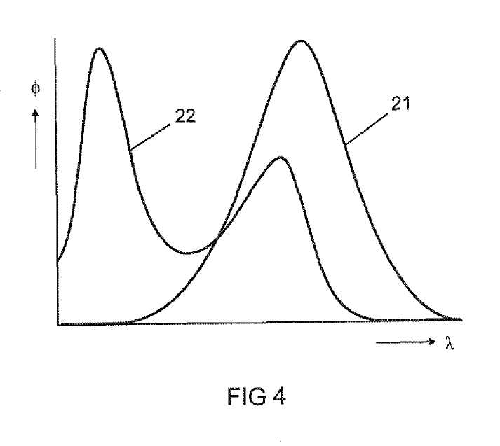

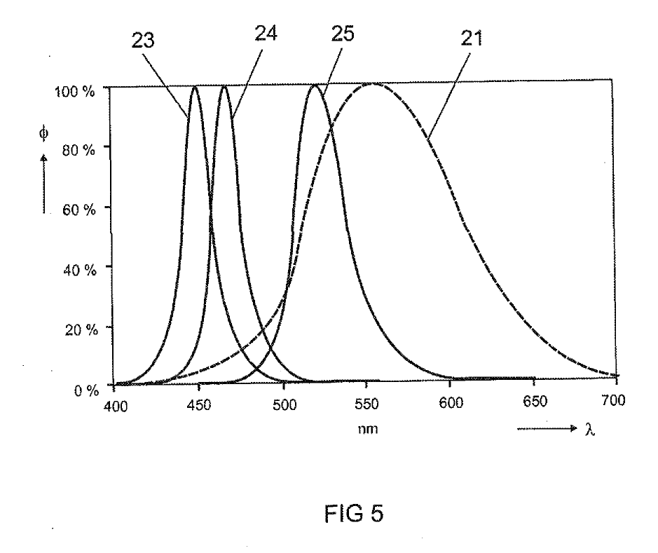

FIG. 4 is a qualitative representation of the spectral sensitivity 22 of the visual organs of nocturnal insects in comparison to the spectral sensitivity 21 of the human eye.

Here, the spectral sensitivities are plotted against the wavelength.

Maxima of the spectral sensitivity of nocturnal insects lie at other, in particular lower wavelengths, than the maximum of the spectral sensitivity of humans.

Nocturnal insects have maxima of spectral sensitivity in the ultraviolet, violet, blue and, to a lesser extent, in the green spectral range. This fact is utilized by the lighting device with the light trap according to the present invention.

The human eye can perceive electromagnetic radiation in a wavelength range of approximately 390 nm to approximately 780 nm. Its maximum spectral sensitivity is in the yellow to yellow-green spectral range. The precise value of the maximum spectral sensitivity of the human eye varies, on the one hand, person to person and, on the other, is dependent upon luminance to which the human eye is adapted.

Luminances in the photopic range, daylight vision, lie above 5 cd/m² luminances in the mesopic range, twilight vision lie between 5 cd/m² and 0.001 cd/m² and luminances in the scotopic range, nighttime vision, lie below 0.001 cd/m². According to the standard DIN EN 13201, in European countries, roads with an medium to high traffic load should be illuminated with a luminance in the range of 0.3 cd/m² to 2 cd/m². Therefore, the required luminances lie within in the mesopic range.

Compared to the spectral sensitivity of the human eye in the photopic range, the maximum spectral sensitivity of the human eye in the mesopic range is slightly displaced toward lower wavelengths.

Taking into account all the factors named above, the maximum of the spectral sensitivity of the human eye in environments with illuminated roads lies in the wavelength range between approximately 500 nm and approximately 560 nm.

FIG. 5 is a graph plotting a first electromagnetic spectrum 23, a second electromagnetic spectrum 24 and a third electromagnetic spectrum 25 of light-emitting diodes such as can be used in the light trap described here. Here, the spectra are plotted in shape of the relative spectral emission against the wavelength.

Moreover, as in FIG. 4, the curve 21 shows the spectral sensitivity of the human eye.

The spectrum 23 has its maximum in the deep-blue range. The spectrum 24 has its maximum in the blue range. The spectrum 25 has its maximum in the green range. The emission lines shown are narrow-band with half-width values around 20 nm in the deep-blue range and blue range or with a half-width value around 35 nm in the green range.

The use of LEDs with narrow-band emission enables the energy consumption of light traps to be reduced compared to that of conventional lighting means.

LEDs and OLEDs also enable the wavelength of the electromagnetic radiation 5 emitted by the light trap 4 to be set to the maxima of the spectral sensitivity of the visual organs of nocturnal insects.

The LEDs used in the light trap 4 emit as little electromagnetic radiation as possible in the ranges in which the human eye has maximum spectral sensitivity.

### LIST OF REFERENCE CHARACTERS

1 Lighting device
2 First light source
3 Electromagnetic radiation with a first electromagnetic spectrum
4 Second light source, light trap, insect trap
5 Electromagnetic radiation with second electromagnetic spectrum
6 Light-exit surface
7 Mast
8 Light
9 Control device
10 Sensor
11 Shading means
21 Spectral sensitivity of the human eye
22 Spectral sensitivity of visual organs of nocturnal insects
23 Spectrum of a deep-blue-emitting light-emitting diode
24 Spectrum of a blue-emitting light-emitting diode
25 Spectrum of a green-emitting light-emitting diode

1-13. (canceled)

14. A lighting device comprising:
a first light source for emitting electromagnetic radiation having a first electromagnetic spectrum; and
a second light source for emitting electromagnetic radiation having a second electromagnetic spectrum,
wherein the first and the second electromagnetic spectrum are different from each other,
wherein an intensity maximum of the first electromagnetic spectrum lies within the range of the spectral sensitivity of the human eye, and
wherein an intensity maximum of the second electromagnetic spectrum lies within the range of the spectral sensitivity of the visual organs of nocturnal insects.

15. The lighting device as claimed in claim 14, wherein the second spectrum has an intensity maximum in one of the following spectral ranges:
ultraviolet spectral range at a wavelength of approximately 340 nm,
blue-violet spectral range at a wavelength of approximately 450 nm, and
blue-green spectral range at a wavelength of approximately 500 nm.

16. The lighting device as claimed in claim 14, wherein the second light source is weakly radiating compared to the first light source.

17. The lighting device as claimed in claim 14, wherein the first light source and/or the second light source comprises one of the following lighting means:
incandescent lamp,
mercury-vapor lamp,
fluorescent lamps,
metal-vapor lamp,
sodium-vapor lamp,
LED or
OLED.

18. The lighting device as claimed in claim 14, wherein the second light source comprises at least one shading means.

19. The lighting device as claimed in claim 18, wherein the shading means has the shape of a hemisphere.

20. The lighting device as claimed in claim 18, wherein the shading means has a bent shape.

21. The lighting device according to claim 18, wherein the shading means is made of an opaque material.

22. The lighting device as claimed in claims 14, with a control device, which is set up to control the electromagnetic spectra and/or the intensities of the emitted electromagnetic radiation from the first light source and/or the second light source individually or jointly.

23. The lighting device as claimed in claim 14, with a sensor for detecting measured variables.

24. The lighting device as claimed in claim 23, wherein the sensor is configured to detect at least one of the following measured variables:
temperature,
atmospheric humidity,
ambient luminosity, and
visibility conditions
at the location of the lighting device.

25. A method for upgrading a lighting device comprising a first light source, wherein the method comprises:
arranging a second light source on the lighting device,
wherein the first light source emits electromagnetic radiation having a first electromagnetic spectrum and the second light source emits electromagnetic radiation having a second electromagnetic spectrum,
wherein the first and the second spectrum are different from each other, and
wherein an intensity maximum of the first electromagnetic spectrum lie within the range of the spectral sensitivity of the human eye and an intensity maximum of the second electromagnetic spectrum lie within the range of the spectral sensitivity of the visual organs of nocturnal insects.

26. The method for upgrading a lighting device as claimed in claim 25 comprising a mast, wherein the second light source is arranged on the mast.

27. The method for upgrading a lighting device as claimed in claim 25 comprising a light, wherein the second light source is arranged on the light.
